(19) United States
(12) Patent Application Publication
(10) Pub. No.: US 2007/0297214 A1
(43) Pub. Date: Dec. 27, 2007

(54) Semiconductor device

(75) Inventor: Hiroki Dembo, Isehara (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 11/806,738

(22) Filed: Jun. 4, 2007

(30) Foreign Application Priority Data
Jun. 9, 2006 (JP) 2006-160516

(51) Int. Cl. G11C 11/24

(52) U.S. Cl. 365/149

(57) ABSTRACT

To provide a semiconductor device in which power consumption at the time of an anti-collision operation is reduced. A semiconductor device includes an arithmetic circuit, a storage device, and circuits for transmitting and receiving signals to and from the outside. The arithmetic circuit includes a central processing unit and a controller. The central processing unit executes a program for using the controller to reduce power consumption when a signal is transmitted to the outside. The program has a structure which includes a plurality of routines. Representatively, the program includes a command determination routine, a UID value processing routine, a mask value comparison routine, an N-slot power consumption reduction routine, an N-slot counter routine, and the like.

### BACKGROUND OF THE INVENTION

1. Field of the Invention

The present invention relates to semiconductor devices. In particular, the present invention relates to semiconductor devices which transmit and receive signals to and from the outside, or so-called IC chips (also referred to as ID chips, IC tags, ID tags, RF tags, wireless tags, electronic tags, or transponders) for RFID (radio frequency identification).

Note that in this specification, a semiconductor device refers to any device which can function by utilizing a semiconductor property.

2. Description of the Related Art

Due to the development of computer technology and improvement of image recognition technology, information identification using a medium such as a barcode has become widespread, and is used for identifying product data or the like. It is expected that the amount of information to be identified will further increase in the future. Meanwhile, information reading and the like using a barcode has disadvantages in that it is necessary for a barcode reader to be in contact with the barcode, and not much information can be stored in the barcode. Therefore, there is a desire for contactless information identification and an increase in the storage capacity of mediums.

To meet this desire, contactless IC chips for RFID (hereinafter referred to as IC chips) and reader/writer devices (also referred to as interrogators; hereinafter referred to as reader/writers) have been developed. An IC chip stores necessary information in a memory circuit in the IC chip, and the information inside is read by a reader/writer using a contactless means, which is generally a wireless means. It is expected that the practical application of information processing devices which read information stored in such IC chips will enable commercial distribution and the like to be simplified and made cheaper, while ensuring high security.

In recent years, tags including an IC chip capable of transmitting and receiving data contactlessly, such as product control tags and inventory control tags, have started to become popular in fields where it is necessary for distribution to be made more efficient. Tags which include such IC chips are designed such that reading and writing of data is performed without contact with an external device, through an antenna which has a form suited to a frequency band used when transmitting and receiving data.

A tag which includes such an IC chip includes both a storage device, which stores an operation procedure (hereinafter referred to as a program) for performing an operation which corresponds to a command transmitted from a reader/writer when transmission and reception of data is performed with the reader/writer, and an arithmetic circuit that operates according to the program. In Reference 1 (Japanese Patent No. 3243591), a method for such an IC chip to conduct a process which corresponds to the command is disclosed.

FIG. 13 shows a block diagram of a specific structure of an IC chip described in Reference 1.

In a conventional IC chip 910 in FIG. 13, a receive signal 911 received by an antenna 901 is input to a power supply circuit 902 and a demodulation circuit 903. Conventionally, the receive signal undergoes processing such as ASK (amplitude shift keying) modulation, which changes the amplitude of a carrier such as 13.56 MHz or 915 MHz, or PSK (phase shift keying) modulation, which changes the phase of a carrier such as 13.56 MHz or 915 MHz, then is transmitted. In FIG. 13 an example is shown where 13.56 MHz is used as the receive signal. In FIG. 13, in order to process the receive signal, a clock signal which serves as a standard is necessary. Here, a 13.56 MHz carrier is used for the clock signal. The receive signal 911 which has been ASK modulated or PSK modulated is demodulated by the demodulation circuit 903. The demodulated signal is transmitted to an arithmetic circuit 904 and analyzed. Based on the analyzed signal, the arithmetic circuit 904 controls the storage device 905 and performs an operation according to an operation procedure written in a program stored in the storage device 905.

When the conventional IC chip performs a transmit operation, based on the operation procedure written in the program stored in the storage device 905, a modulation circuit 906 modulates the carrier by a signal encoded by the arithmetic circuit 904, and thereby a transmit signal 912 is transmitted from the antenna 901.

Further, a communication signal which is input to the power supply circuit 902 is rectified. Furthermore, electric power generated by the rectification is supplied to the demodulation circuit 903, the arithmetic circuit 904, the storage device 905, the modulation circuit 906, and the like. The conventional IC chip operates in this way.

Further, Reference 1 describes a beneficial effect in that in accordance with the above-described operations, just by rewriting the program stored in the storage device 905 to match an intended use of an IC chip, an IC chip for a selected intended use can be obtained.

Meanwhile, in a case where a plurality of IC chips are communicating with a reader/writer, a program for performing an operation corresponding to a collision prevention function (hereinafter referred to as anti-collision) is used in the IC chip in order to avoid the transmit and receive signals between the plurality of IC chips and the reader/writer from overlapping with each other.

A procedure in which the arithmetic circuit repeatedly performs a transmit operation a plurality of times is written into the program for performing the operation that corresponds to anti-collision. Therefore, the arithmetic circuit repeats the transmit operation in accordance with the program at the time of an anti-collision operation.

### SUMMARY OF THE INVENTION

However, there is a problem with the conventional IC chip which includes an arithmetic circuit and a storage device in that due to the size of circuits included in the arithmetic circuit and the storage device, power consumption increases. Further, there is a problem in that when the arithmetic circuit, the storage device, and the modulation circuit operate simultaneously, that is, when a communication signal is transmitted from the antenna by the modulation circuit modulating a carrier, electric power is not stable and a normal modulation cannot be performed.

In view of the foregoing, an object of the present invention is to provide a semiconductor device in which power consumption at the time of an anti-collision operation is reduced.

A semiconductor device of the invention includes a central processing unit, a controller, a storage device, and circuits for transmitting and receiving signals to and from the outside. A program for reducing the power consumption of the central processing unit when a signal is transmitted to the outside, using the controller is stored in the storage device.

The program has a structure which includes a plurality of routines. As representative examples of the plurality of routines, a command determination routine, a UID value processing routine, a mask value comparison routine, an N-slot power consumption reduction routine, an N-slot counter routine, and the like can be given.

Further, the controller has a function of stopping the central processing unit when a signal is transmitted to the outside. When the program is executed, the controller executes this function.

Further, in the invention, the storage device may have a structure which includes a ROM and a RAM.

Further, in the invention, the controller may have a structure which includes a CPU interface, a control register, a code extraction circuit, and an encoder circuit.

Further, in the invention, the circuits for transmitting and receiving signals to and from the outside may have a structure which includes an antenna, a resonant circuit, a power supply circuit, a reset circuit, a clock generator circuit, a demodulation circuit, a modulation circuit, and a power supply generating circuit.

According to the invention, in a semiconductor device having an anti-collision function which repeatedly performs a transmit operation a plurality of times, by using the controller to stop the central processing unit when a signal is transmitted to the outside, the amount of power consumed when transmitting the signal to the outside is reduced. Therefore, when the arithmetic circuit operates simultaneously with the storage device and the modulation circuit, that is, when a communication signal is transmitted from the antenna by the modulation circuit modulating a carrier, electric power can be stabilized and operation at the time of transmission can be performed reliably. Further, in a semiconductor device having a function of repeatedly performing a transmit operation a plurality of times, it is not necessary to remake the semiconductor device from the stage of mask design due to a change in specifications accompanying a change in a method of operation. Therefore, reduction in manufacturing cost and manufacturing time can be achieved. Further, there are no concerns such as whether a semiconductor device remade due to a change in mask design will be defective.

### BRIEF DESCRIPTION OF DRAWINGS

FIG. 1 illustrates a structure of a semiconductor device of the invention.

FIGS. 2A and 2B illustrate parts of a structure of a semiconductor device of the invention.

FIG. 3 illustrates a structure of data which a semiconductor device of the invention receives.

FIG. 4 illustrates a routine that a semiconductor device of the invention executes.

FIG. 5 illustrates a routine that a semiconductor device of the invention executes.

FIG. 6 illustrates a routine that a semiconductor device of the invention executes.

FIG. 7 illustrates a routine that a semiconductor device of the invention executes.

FIG. 8 illustrates a routine that a semiconductor device of the invention executes.

FIGS. 9A and 9B illustrate a top view and a cross section of a structure of a semiconductor device of the invention.

FIGS. 10A to 10D illustrate top views of structures of antennas which can be applied to a semiconductor device of the invention.

FIGS. 11A and 11B illustrate top views of a structure of a semiconductor device of the invention.

FIGS. 12A to 12E illustrate top views of modes of use of a semiconductor device of the invention.

FIG. 13 illustrates a structure of a conventional semiconductor device.

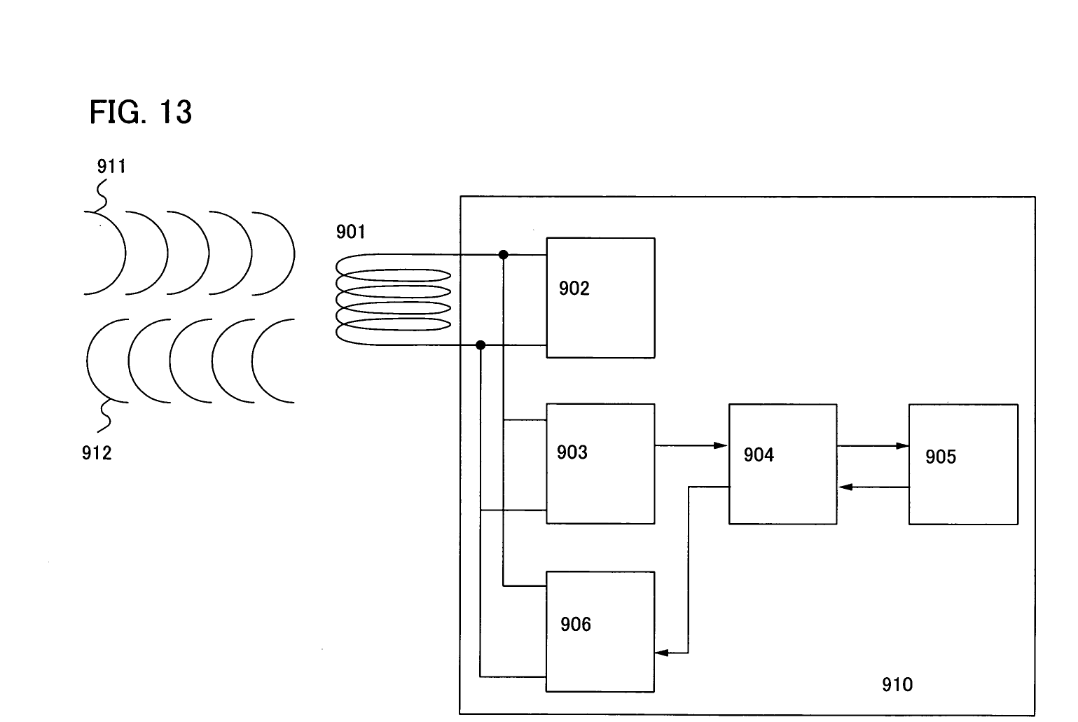

FIGS. 14A to 14C illustrate specific examples of routines executed by a semiconductor device of the invention.

FIGS. 15A to 15C illustrate specific examples of routines executed by a semiconductor device of the invention.

FIG. 16 illustrates specific examples of routines executed by a semiconductor device of the invention.

FIG. 17 is a timing chart of a semiconductor device of the invention.

FIG. 18 is a timing chart of a semiconductor device of the invention.

### DETAILED DESCRIPTION OF THE INVENTION

### Embodiment Mode

An embodiment mode and embodiments of the invention will be described below, with reference to the drawings. However, the invention can be carried out in many different modes, and it will be readily apparent to those skilled in the art that various changes can be made to the modes and details described herein without departing from the spirit and scope of the invention. Therefore, the invention should not be construed as being limited to the description of the embodiment mode and embodiments. Note that in the drawings which illustrate the embodiment mode and embodiments, parts which are the same or which have the same function are assigned the same reference numerals, and repetitive description of such parts is omitted.

In this embodiment mode, a device structure of the invention for realizing a function of reducing power consumption at the time of an anti-collision operation and flowcharts relating to the invention will be described.

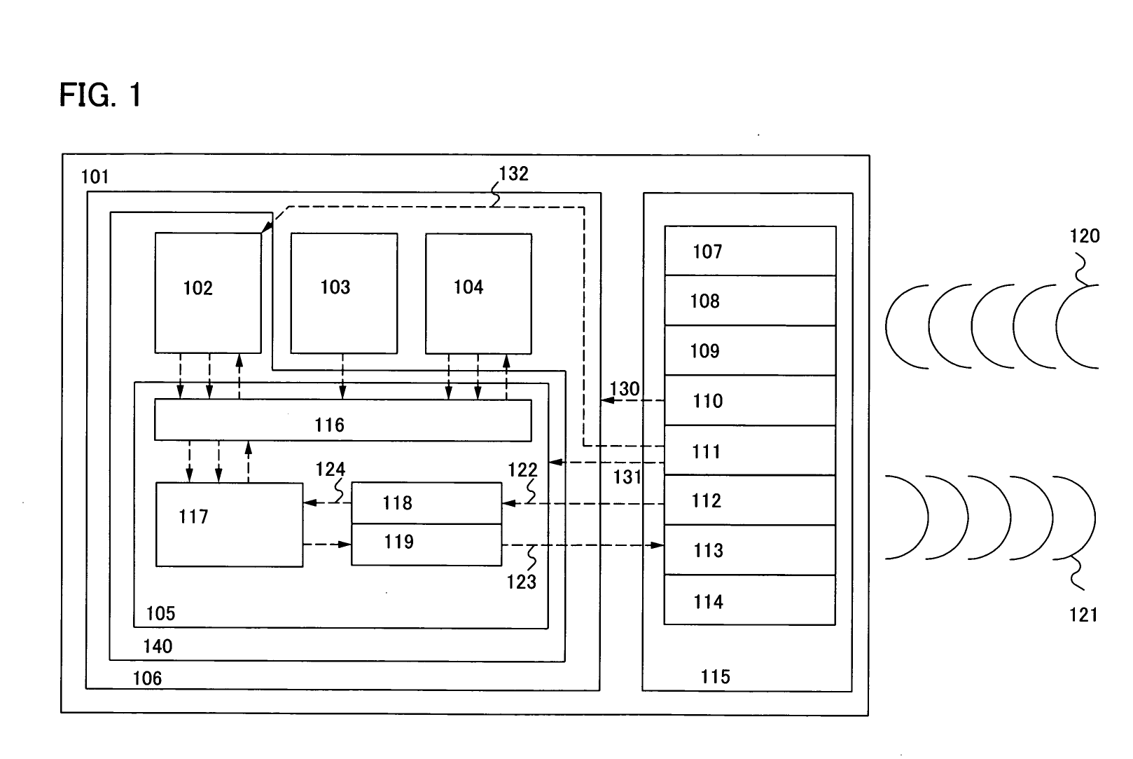

FIG. 1 shows a block diagram of a semiconductor device of the invention which has a function of reducing power consumption at the time of an anti-collision operation.

In FIG. 1, a semiconductor device 101 includes a digital portion 106 and an analog portion 115. The digital portion 106 includes a ROM (also referred to as a read-only memory) 103, a RAM (also referred to as a random-access memory) 104, and a control circuit 140. Further, the analog portion 115 includes an antenna 107, a resonant circuit 108, a power supply circuit 109, a reset circuit 110, a clock generator circuit 111, a demodulation circuit 112, a modulation circuit 113, and a power supply control circuit 114. Furthermore, the control circuit 140 includes a CPU (also referred to as a central processing unit) 102 and a controller 105. The controller 105 includes a CPU interface (CPUIF) 116, a control register 117, a code extraction circuit 118, and an encoder circuit 119. Note that in FIG. 1, as communication signals, a receive signal 120 and a transmit signal 121 are shown separately for simplicity of description. However, they actually overlap, and are transmitted and received between the semiconductor device 101 and a reader/writer device simultaneously. After the receive signal 120 is received by the antenna 107 and the resonant circuit 108, it is demodulated by the demodulation circuit 112. Further, after the transmit signal 121 is modulated by the modulation circuit 113, it is transmitted from the antenna 107. Note that the receive signal 120 and the transmit signal 121 are named with respect to the semiconductor device, and description is made assuming the semiconductor device receives a signal from the outside and transmits a signal to the outside. In this specification, a signal from a reader/writer that a semiconductor device receives, in other words, a signal that the reader/writer transmits, is referred to as an outside signal, and reception of an outside signal by a semiconductor device and transmission of an outside signal by the reader/writer is referred to as reception and transmission of outside signals.

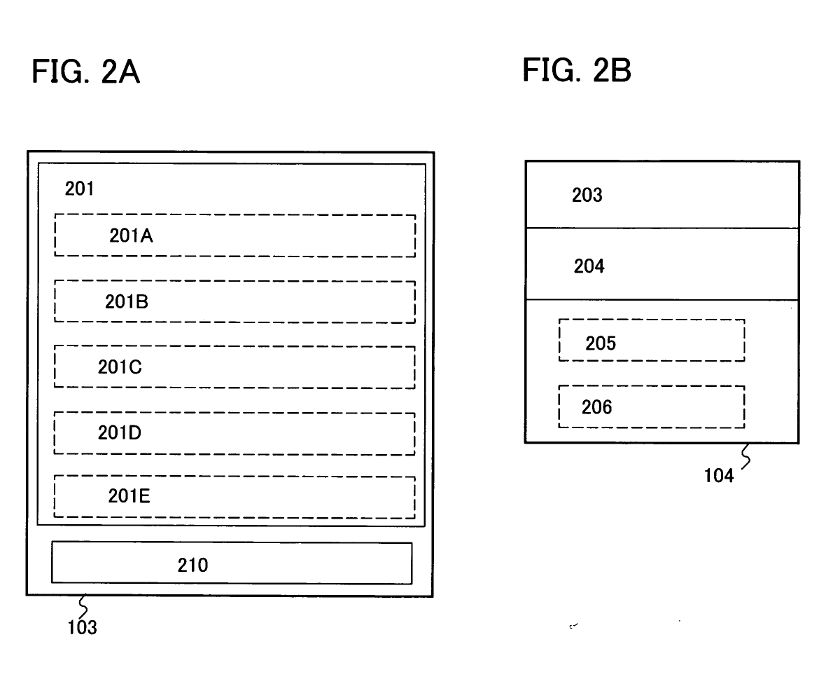

As shown in FIGS. 2A and 2B, data of a program (hereinafter referred to as a main program 201) which functions when receive data which is received from the reader/writer is processed, and a UID (unique identifier) 210 are stored in the ROM 103, and processing data from when the program functions is stored in the RAM 104. For the ROM 103, a nonvolatile memory such as a mask ROM (a read-only memory), an organic memory, or an EEPROM can be used. For the RAM 104, a volatile memory such as a static random-access memory (SRAM) or a dynamic random-access memory (DRAM) can be used. Further, routines for reducing the power consumption of the semiconductor device are included in data of the main program 201.

Further, the main program 201 is stored in the ROM 103 (see FIG. 2A). A command determination routine 201A, a UID value processing routine 201B, a mask value comparison routine 201C, an N-slot power consumption reduction routine 201D, and an N-slot counter routine 201E are stored in the main program 201.

The command determination routine 201A refers to a program code having a function of executing a decision process concerning a specific command.

The UID value processing routine 201B refers to a program code having a function of executing UID value processing in an anti-collision process.

The mask value comparison routine 201C refers to a program code having a function of executing comparison processing of a mask value in the anti-collision process.

The N-slot power consumption reduction routine 201D refers to a program code having a function of executing power consumption reduction processing in the anti-collision process.

The N-slot counter routine 201E refers to a program code having a function of executing comparison processing of a slot counter value and a slot register value used in the anti-collision process.

These plurality of routines will be described in greater detail below.

The RAM 104 includes a transmit data register 203, a receive data register 204, a slot register 205, a comparison register 206, and the like (see FIG. 2B).

The transmit data register 203 has a function of storing data transmitted by the semiconductor device.

The receive data register 204 has a function of storing data that the semiconductor device receives.

The slot register 205 is a region that stores a slot register value. The slot register value is a slot that transmits data in the N-slot power consumption reduction routine 201D, which will be described below. The slot is the number of semiconductor devices that can be anti-collision processed simultaneously.

The comparison register 206 is a region that stores a mask value obtained from a value which starts from a bit which is x bits (where x equals a pointer value) from the least significant bit of a UID value.

Since the amount of information in the RAM 104 is less than that in the ROM 103, the area of the RAM 104 is small.

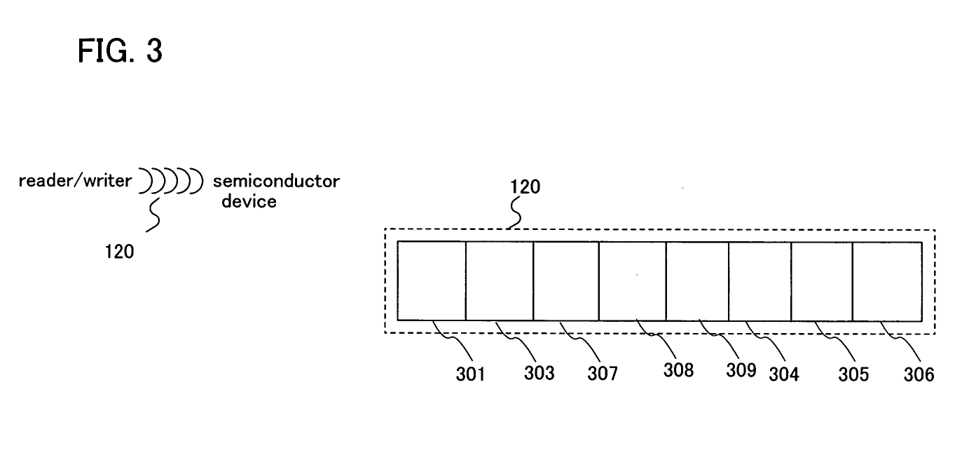

FIG. 3 shows a structure of a signal transmitted from the reader/writer to the semiconductor device, in other words, the receive signal 120 which the semiconductor device receives. The receive signal 120 includes an SOF (start of frame) 301, a command 303, a pointer 307, a mask length 308, a mask value 309, data 304, a CRC (cyclic redundancy check) 305, and an EOF (end of frame) 306.

The SOF 301 and the EOF 306 simply show the start and end of the signal.

The command 303 is a signal which stipulates whether or not the reader/writer performs an anti-collision process. In a case where an anti-collision process is to be performed, the command 303 has the information “1”. In cases other than that (commands to perform normal reading or the like), the command 303 has information other than “1”.

The data 304 includes data for an anti-collision process.

The CRC 305 has information which is a unique value generated from data in order to prevent misidentification of data. The CRC 305 includes information which is a CRC flag “1” in a case where the data is correct, and a CRC flag “0” in a case where the data is incorrect.

The pointer 307 shows addresses of signals inside the UID of each semiconductor device.

The mask length 308 shows the length of a mask value of a signal transmitted from the reader/writer to the semiconductor device.

The mask value 309 shows the mask value of the signal transmitted from the reader/writer to the semiconductor device.

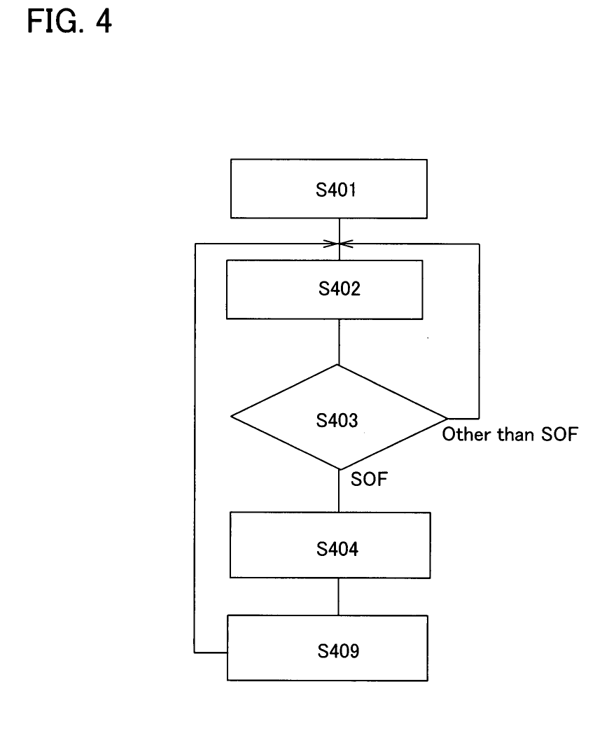

Next, an operation of the main program in the semiconductor device in FIG. 1 will be described while referring to the flowchart in FIG. 4.

First, the reset circuit 110 included in the semiconductor device receives the receive signal 120 and outputs a reset signal 130 to the digital portion 106 to reset the digital portion 106 (S401). When the digital portion 106 is reset, the clock generator circuit 111 outputs a system clock signal 131 to the controller 105 and starts an operation of the controller 105. When the digital portion 106 is reset, the demodulation circuit 112 starts demodulating the receive signal 120, and outputs the demodulated receive data 122 to the code extraction circuit 118. The code extraction circuit 118 extracts a control code from the demodulated receive data 122 and writes the control code to the control register 117 as a control signal 124. When the signal from the code extraction circuit 118 is written to the control register 117, the clock generator circuit 111 starts supplying CPU clock signals 132 to the CPU 102.

When the signal from the code extraction circuit 118 is written to the control register 117, the CPU included in the semiconductor device starts an operation (S402). The CPU 102 determines whether or not an SOF (start of frame) is included in the control code in the control register 117 (S403). If an SOF is included in the control code, the main program is read from the ROM 103 (S404). Next, the main program is executed (S409). On the other hand, if an SOF is not included in the control code in the control register 117, the CPU returns to the state it was in after the initial reset 401. Note that after the main program has been executed, the CPU 102 returns to the state it was in after the initial reset (S401).

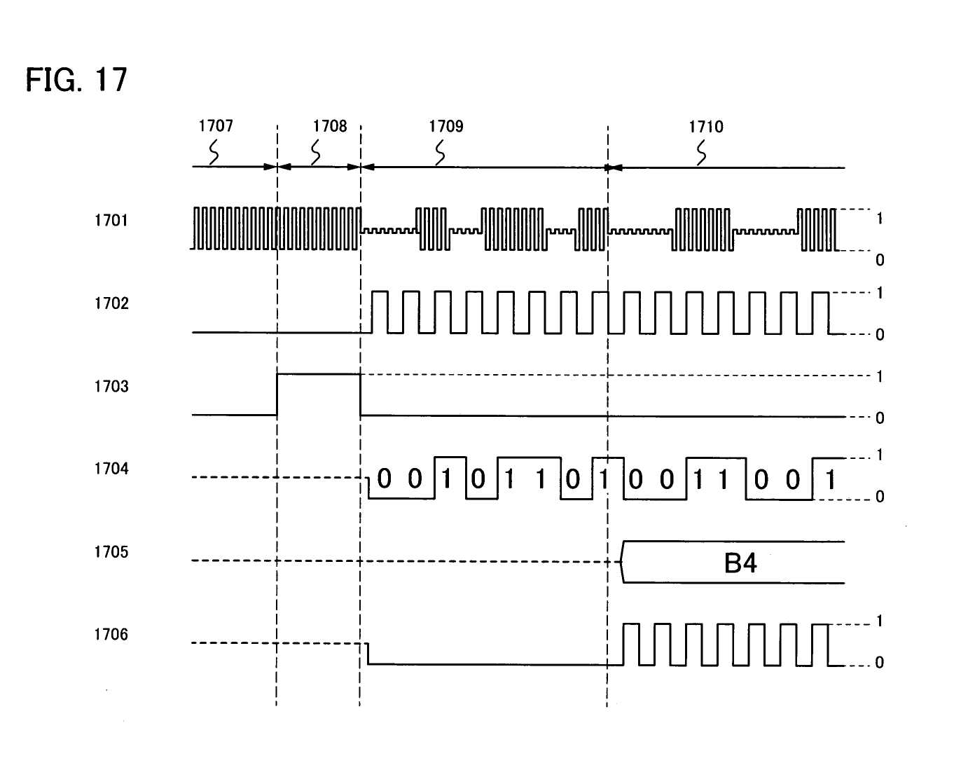

Next, a signal related to reception will be described with reference to the timing chart shown in FIG. 17. A first signal 1701 corresponds to the receive signal 120 in FIG. 1. A second signal 1702 corresponds to the system clock signal 131 shown in FIG. 1. A third signal 1703 corresponds to the reset signal 130 for the digital portion 106 shown in FIG. 1. A fourth signal 1704 corresponds to the receive data 122 shown in FIG. 1. A fifth signal 1705 corresponds to the control signal 124 shown in FIG. 1. A sixth signal 1706 corresponds to the CPU clock signal 132 shown in FIG. 1.

In FIG. 17, when the third signal 1703 is in a “1” period, the digital portion is reset. The period of time until the reset is performed will be referred to as a period of awaiting reception 1707. The period of time when the reset is being performed will be referred to as a reset period 1708. After the reset period 1708, the clock generator circuit 111 starts outputting “0” and “1” alternately to the second signal 1702. A signal which alternately repeats “0” and “1” is referred to as a clock. The digital portion 106 starts an operation based on the clock. Note that here, low potential corresponds to “0” and high potential corresponds to “1”.

After the reset period 1708, the demodulation circuit 112 starts demodulating the first signal 1701. The first signal 1701 is an electromagnetic wave which oscillates at a carrier wave frequency. “Demodulation” refers to conversion to a digital value of “1” when the amplitude is maximum and “0” when the amplitude is minimum. The first signal 1701 is demodulated by the demodulation circuit 112 and output to the code extraction circuit 118 as the fourth signal 1704. The code extraction circuit 118 extracts the fifth signal 1705 from the fourth signal 1704 and writes the fifth signal 1705 to the control register 117. Specifically, the code extraction circuit 118 extracts the binary bits of the fourth signal 1704 as a hexadecimal figure which is the fifth signal 1705. Further, the clock generator circuit 111 starts outputting clocks to the sixth signal 1706 when the fifth signal 1705 is written to the control register 117. Note that the period of time from when the reset period 1708 has finished to when the writing to the control register 117 has finished is a reception processing period 1709.

The CPU 102 starts an operation when the signal is written to the control register 117. The period of time after the writing has finished is referred to as a computation period 1710.

Note that preferably a structure where a power supply voltage is not supplied to the digital portion 106 in the period of awaiting reception 1707 is employed, since power consumption can be reduced by employing such a structure. Specifically, a power supply line of the digital portion 106 is preferably independent of a power supply line of the other circuits, and an electrical connection between the power supply line of the digital portion 106 and the power supply circuit 109 is preferably cut off by the power supply control circuit 114.

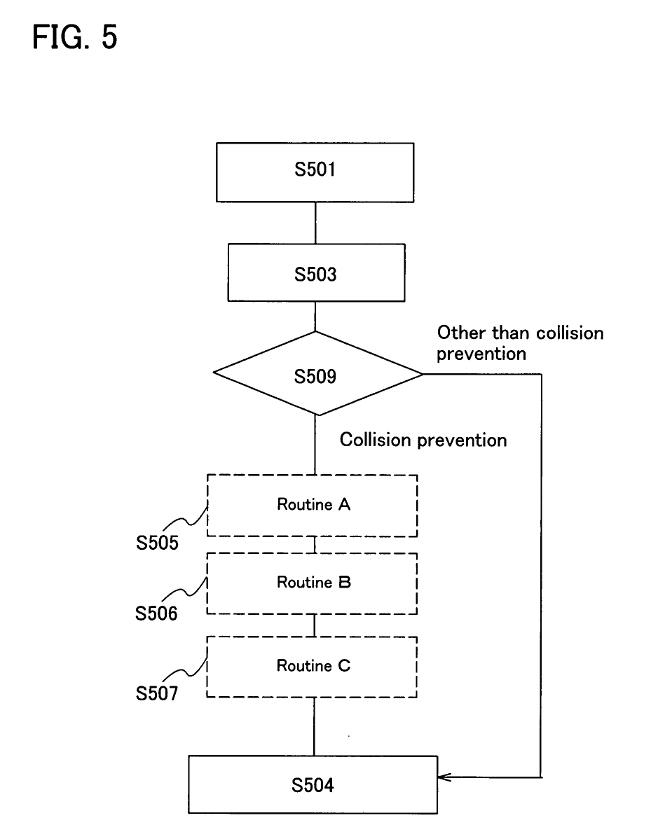

Next, routines in the main program for realizing a function shown in FIG. 1 of reducing power consumption at the time of an anti-collision operation will be described with reference to FIGS. 5 to 8.

First, an operation of the main program will be described while referring to the flowchart shown in FIG. 5. The CPU 102 reads the command determination routine 201A from the ROM 103, and then starts the command determination routine 201A (S501). The CPU 102 reads a command code of the control register 117 and writes the command code to the RAM 104. That is, the command is acquired (S503). Depending on the type of command code, the CPU 102 executes either a collision prevention process or a process other than collision prevention (S509). In addition, the CPU 102 can execute a plurality of routines (routine A (S505), routine B (S506), and routine C (S507), in FIG. 5). Finally, the CPU 102 terminates the plurality of routines for reducing power consumption at the time of an anti-collision operation (S504).

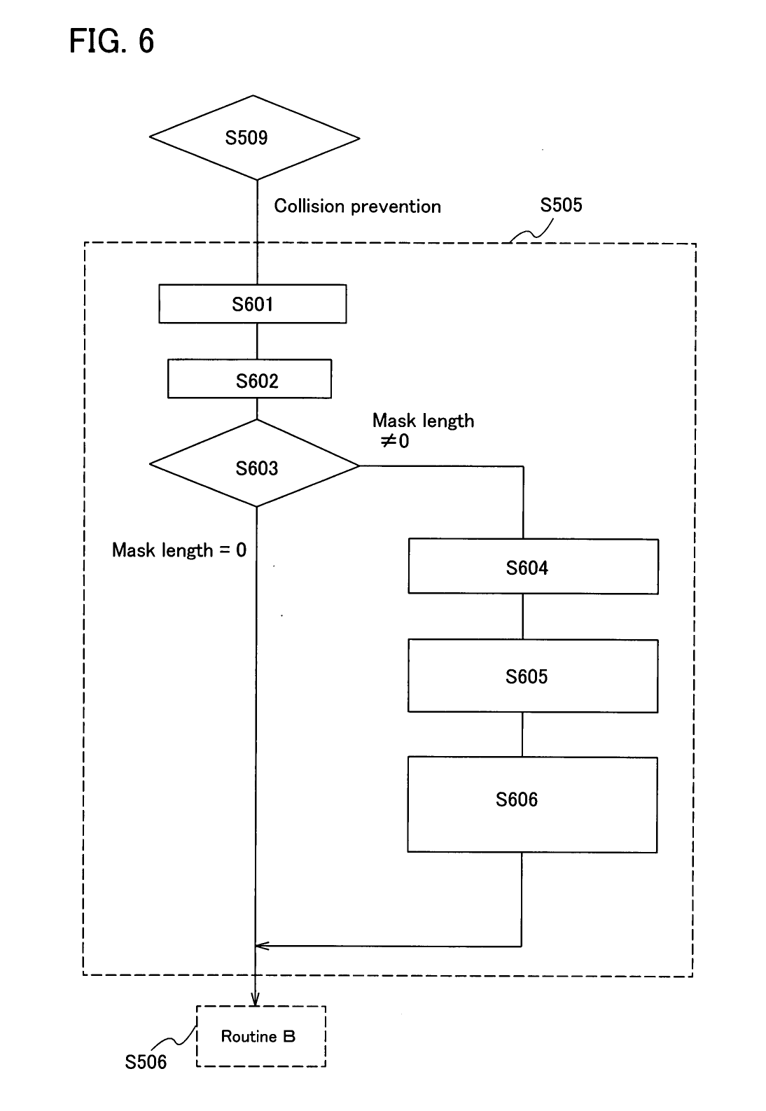

Next, processing details of the plurality of routines in the semiconductor device in FIG. 1 will be described while referring to the flowchart in FIG. 6.

FIG. 6 shows a flowchart of a UID value processing routine (routine A in FIG. 5). Here, a UID value is processed, and a process that stores a slot in the slot register 205 is performed. The CPU 102 reads a pointer value of the control register 117 and writes the pointer value to the RAM 104 (pointer acquisition S601). The CPU 102 reads a mask length value of the control register 117 and writes the mask length value to the RAM 104 (mask length acquisition S602). The CPU 102 splits the process according to a mask length value. The CPU 102 determines the mask length (S603). Only when the mask length value is a value other than 0, the CPU 102 reads a value which starts from a bit which is x bits (where x equals a pointer value) from the least significant bit of the UID value (S604), right-shifts that value by a number of bits equal to [the mask length value+the pointer value] (S605), and stores the value of a number of least significant bits equal to logN/log2 bits (which in this embodiment mode is 4 bits, since N is 16) in the slot register 205 of the RAM 104 (see FIG. 2B). That is, the CPU 102 stores a value which starts from a bit which is y bits (where y equals the mask length) from the pointer of the UID value, in the slot register 205 (S606). The value stored in the slot register 205 at this time corresponds to a slot register value.

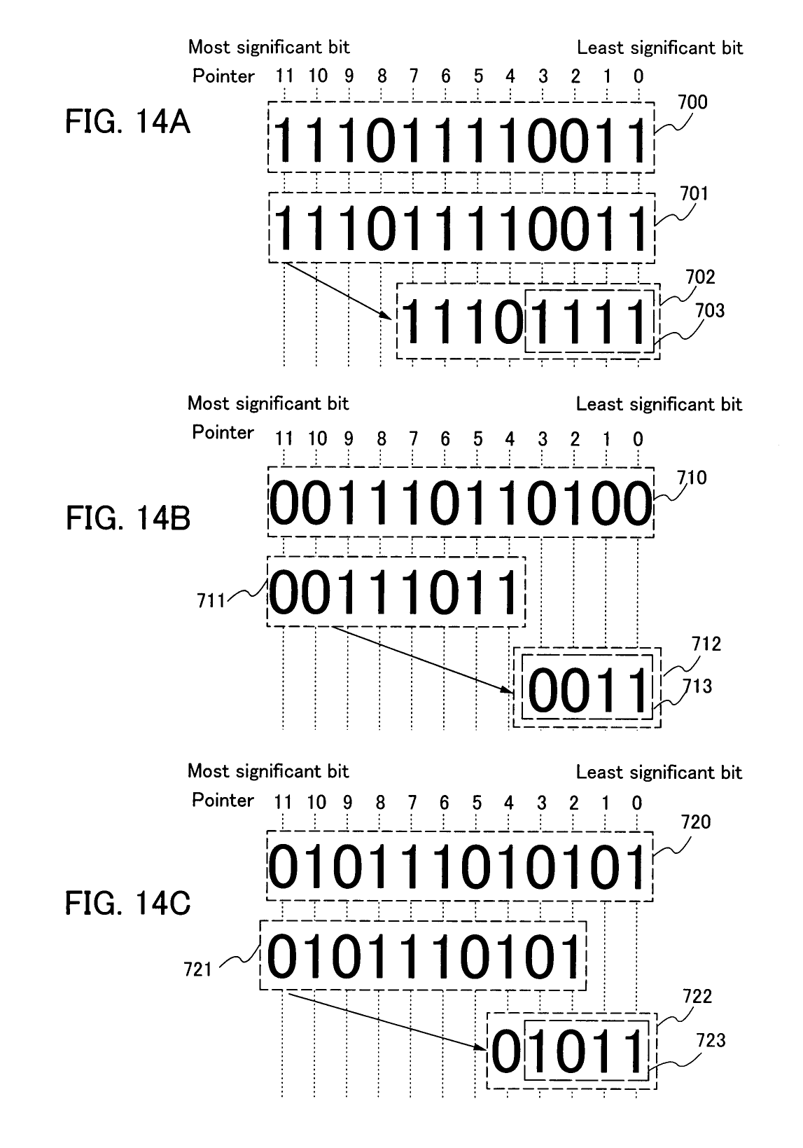

FIGS. 14A to 14C specifically show processes of the UID value processing routine in FIG. 6. Values used as examples here are shown in Table 1. Note that the UID values are shown in binary notation and the pointer values and mask lengths are shown in decimal notation. In the binary notation, the rightmost end corresponds to the least significant bit and the leftmost end corresponds to the most significant bit, and bits are given addresses in sequence from right to left starting with 0. The pointer value is a value which indicates an address.

TABLE 1

| | UID value | Pointer value | Mask length |
|---|---|---|---|
| Example 1 | 111011110011 | 0 | 4 |
| Example 2 | 001110110100 | 4 | 4 |
| Example 3 | 010111010101 | 2 | 5 |

When a UID value 111011110011 from Example 1 in Table 1 (indicated by reference numeral 700 in FIG. 14A) is used in the UID value processing routine, the CPU 102 reads a value which starts from a bit which is x bits (where x equals the pointer value, which is 0 here) from the least significant bit of the UID value, in S604. Specifically, the CPU 102 reads 111011110011, indicated by reference numeral 701 in FIG. 14A. Next, the CPU 102 right-shifts that value by a number of bits equal to [the mask length value (4)+the pointer value (0)], that is, by four bits, in S605. As a result of the right-shift, the value becomes 11101111, indicated by reference numeral 702 in FIG. 14A. Finally, the CPU 102 stores the value of the 4 least significant bits in the slot register 205, in S606. Specifically, the CPU 102 stores 1111, indicated by reference numeral 703 in FIG. 14A, in the slot register 205.

When a UID value 001110110100 from Example 2 in Table 1 (indicated by reference numeral 710 in FIG. 14B) is used in the UID value processing routine, the CPU 102 reads a value which starts from a bit which is x bits (where x equals the pointer value, which is 4 here) from the least significant bit of the UID value, in S604. Specifically, the CPU 102 reads 00111011, indicated by reference numeral 711 in FIG. 14B. Next, the CPU 102 right-shifts that value by a number of bits equal to [the mask length value (4)+the pointer value (4)], that is, by 8 bits, in S605. As a result of the right-shift, the value becomes 0011, indicated by reference numeral 712 in FIG. 14B. Finally, the CPU 102 stores the value of the 4 least significant bits in the slot register 205, in S606. Specifically, the CPU 102 stores 0011, indicated by reference numeral 713 in FIG. 14B, in the slot register 205.

When a UID value 010111010101 from Example 3 in Table 1 (indicated by reference numeral 720 in FIG. 14C) is used in the UID value processing routine, the CPU 102 reads a value which starts from a bit which is x bits (where x equals the pointer value, which is 2 here) from the least significant bit of the UID value, in S604. Specifically, the CPU 102 reads 0101110101, indicated by reference numeral 721 in FIG. 14C. Next, the CPU 102 right-shifts that value by a number of bits equal to [the mask length value (5)+the pointer value (2)], that is, by 7 bits, in S605. As a result of the right-shift, the value becomes 01011, indicated by reference numeral 722 in FIG. 14C. Finally, the CPU 102 stores the value of the 4 least significant bits in the slot register 205, in S606. Specifically, the CPU 102 stores 1011, indicated by reference numeral 723 in FIG. 14C, in the slot register 205.

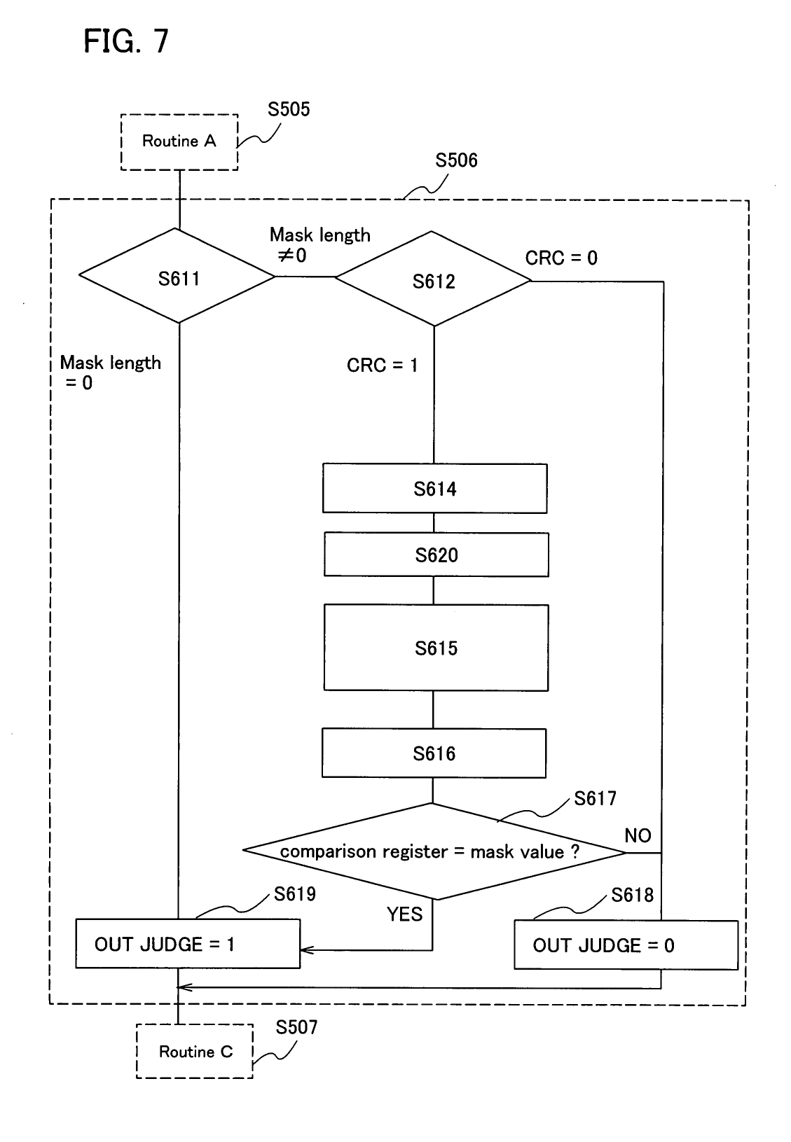

Next, a flowchart of the mask value comparison routine 201C is shown in FIG. 7 (routine B in FIG. 5). Here, a process which determines whether a mask value included in information transmitted from the reader/writer corresponds to a value of the UID of each semiconductor device is performed. The CPU 102 splits the process according to a mask length value. The CPU 102 determines the mask length (S611). When the mask length value is 0, an OUTJUDGE flag stored in the RAM is set to 1 (S619).

Meanwhile, when the mask length value is a value other than 0, the CPU 102 splits the process according to a value of a CRC flag (S612). The CPU 102 determines the CRC (S612). When the CRC flag is 0, the OUTJUDGE flag is set to 0. Further, when the CPU 102 determines the CRC (S612) and the CRC flag is 1, the CPU 102 reads values which start from a bit which is x bits (where x equals a pointer value) from the least significant bit of the UID value of each semiconductor device (S614). Next, the read value of the UID is right-shifted by a number of bits equal to the pointer value (S620), and the value of a number of least significant bits equal to the mask length is then stored in the comparison register 206 (S615). Finally, the CPU 102 reads the mask value stored in the control register 117 (S616) and compares the values stored in the comparison register 206 (the values which start from a bit which is x bits (where x equals the pointer value) from the least significant bit of the UID value of each semiconductor device) with the mask value (a mask value which is transmitted from the reader/writer and stored in the control register 117) (S617). If the values correspond, the CPU 102 sets the OUTJUDGE flag to 1 (S619). On the other hand, if they do not correspond, the CPU 102 sets the OUTJUDGE flag to 0 (S618).

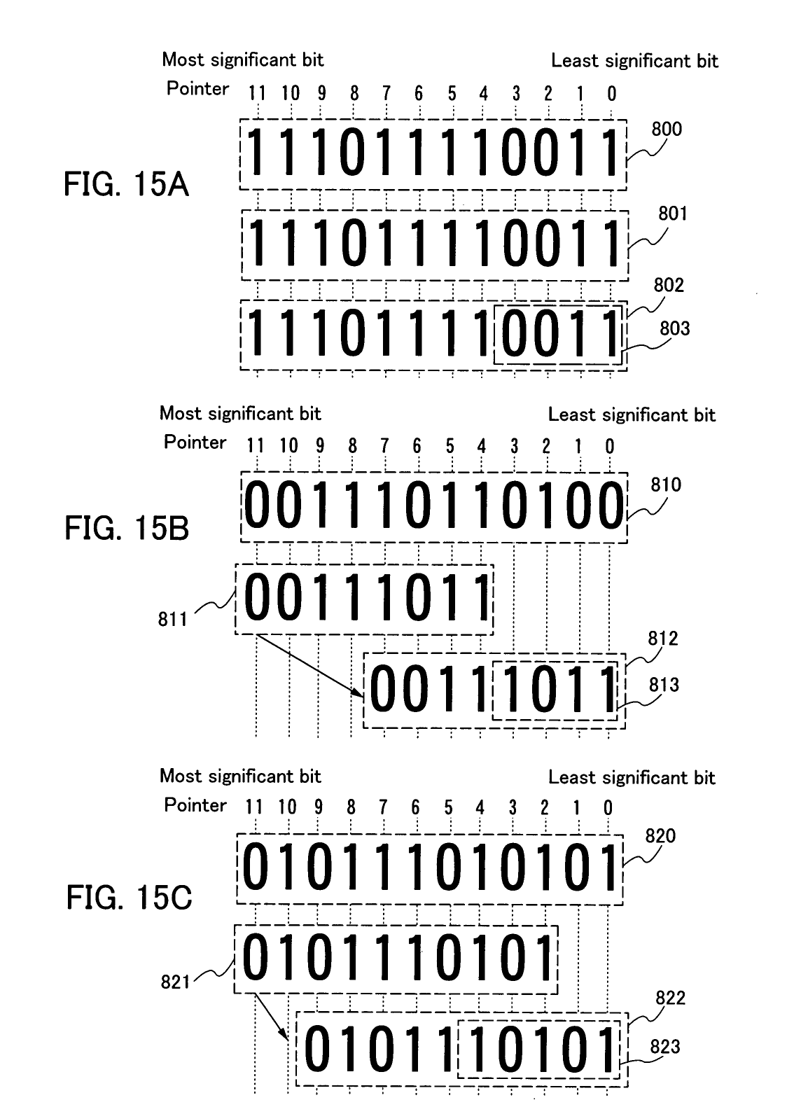

FIGS. 15A to 15C specifically show processes of the mask value comparison routine in FIG. 7. Values used as examples here are shown in Table 2. Note that the UID values and mask values are shown in binary notation and the pointer values and mask lengths are shown in decimal notation. In the binary notation, the rightmost end corresponds to the least significant bit and the leftmost end corresponds to the most significant bit, and bits are given addresses in sequence from right to left starting with 0. The pointer value is a value which indicates an address.

TABLE 2

| | UID value | Pointer value | Mask value | Mask length |
|---|---|---|---|---|
| Example 1 | 111011110011 | 0 | 0011 | 4 |
| Example 2 | 001110110100 | 4 | 0000 | 4 |
| Example 3 | 010111010101 | 2 | 10101 | 5 |

When a mask value 0011 of the UID value 111011110011 (indicated by reference numeral 800 in FIG. 15A) from Example 1 in Table 2 is used in the mask value comparison routine, the CPU 102 reads a value which starts from a bit which is x bits (where x equals a pointer value, which is 0 here) from the least significant bit of the UID value, in S614. Specifically, the CPU 102 reads 111011110011, indicated by reference numeral 801 in FIG. 15A. Next, the CPU 102 right-shifts the read value of the UID by a number of bits equal to the pointer value (0), that is, by 0 bits. As a result of the right-shift, the value becomes 111011110011, indicated by reference numeral 802 in FIG. 15A. Next, in S615, the CPU 102 stores the value of a number of least significant bits of the read value of the UID which is equal to the mask length (4), in the comparison register 206. Specifically, the CPU 102 stores 0011, indicated by reference numeral 803 in FIG. 15A, in the comparison register 206. Finally, the CPU 102 compares the value stored in the comparison register 206 with the mask value. If the values correspond, the OUTJUDGE flag is set to 1, and if they do not, the OUTJUDGE flag is set to 0. Specifically, the CPU 102 compares the value 0011, which is indicated by reference numeral 803 in FIG. 15, with the mask value 0011, and because they correspond, the OUTJUDGE flag is set to 1.

When a mask value 0000 of the UID value 001110110100 (indicated by reference numeral 810 in FIG. 15B) from Example 2 of Table 2 is used in a mask value comparison routine, the CPU 102 reads a value which starts from a bit which is x bits (where x equals the pointer value, which is 4 here) from the least significant bit of the UID value, in S614. Specifically, the CPU 102 reads 00111011, indicated by reference numeral 811 in FIG. 15B. Next, the CPU 102 right-shifts the read value of the UID by a number of bits equal to the pointer value (4), that is, by 4 bits. As a result of the right-shift, the value becomes 00111011, indicated by reference numeral 812 in FIG. 15B. Next, in S615, the CPU 102 stores the value of a number of least significant bits of the read value of the UID which is equal to the mask length (4) in the comparison register 206. Specifically, the CPU 102 stores 1011, indicated by reference numeral 813 in FIG. 15B, in the comparison register 206. Finally, the CPU 102 compares the value stored in the comparison register 206 with the mask value. When the values correspond, the OUTJUDGE flag is set to 1, and when they do not correspond, the OUTJUDGE flag is set to 0. Specifically, the CPU 102 compares 1011, which is indicated by reference numeral 813 in FIG. 15B, with the mask length 0000, and because they do not correspond, the OUTJUDGE flag is set to 0.

When a mask value 10101 of the UID value 010111010101 (indicated by reference numeral 820 in FIG. 15C) from Example 3 of Table 2 is used in a mask value comparison routine, the CPU 102 reads a value starts from a bit which is x bits (where x equals the pointer value, which is 2 here) from the least significant bit of the UID value, in S614. Specifically, the CPU 102 reads 0101110101, indicated by reference numeral 821 in FIG. 15C. Next, the CPU 102 right-shifts the read value of the UID by a number of bits corresponding to the pointer value (2), that is, by 2 bits. As a result of the right-shift, the value becomes 0101110101, indicated by reference numeral 822 in FIG. 15C. Next, in S615, the CPU 102 stores the value of a number of least significant bits of the read value of the UID which is equal to the mask length (5) in the comparison register 206. Specifically, the CPU 102 stores 10101, indicated by reference numeral 823 in FIG. 15C, in the comparison register 206. Finally, the CPU 102 compares the value stored in the comparison register 206 with the mask value. When the values correspond to each other, the OUTJUDGE flag is set to 1, and when they do not correspond, the OUTJUDGE flag is set to 0. Specifically, the CPU 102 compares 10101, which is indicated by reference numeral 823 in FIG. 15C, with the mask value 10101, and because they correspond, the OUTJUDGE flag is set to 1.

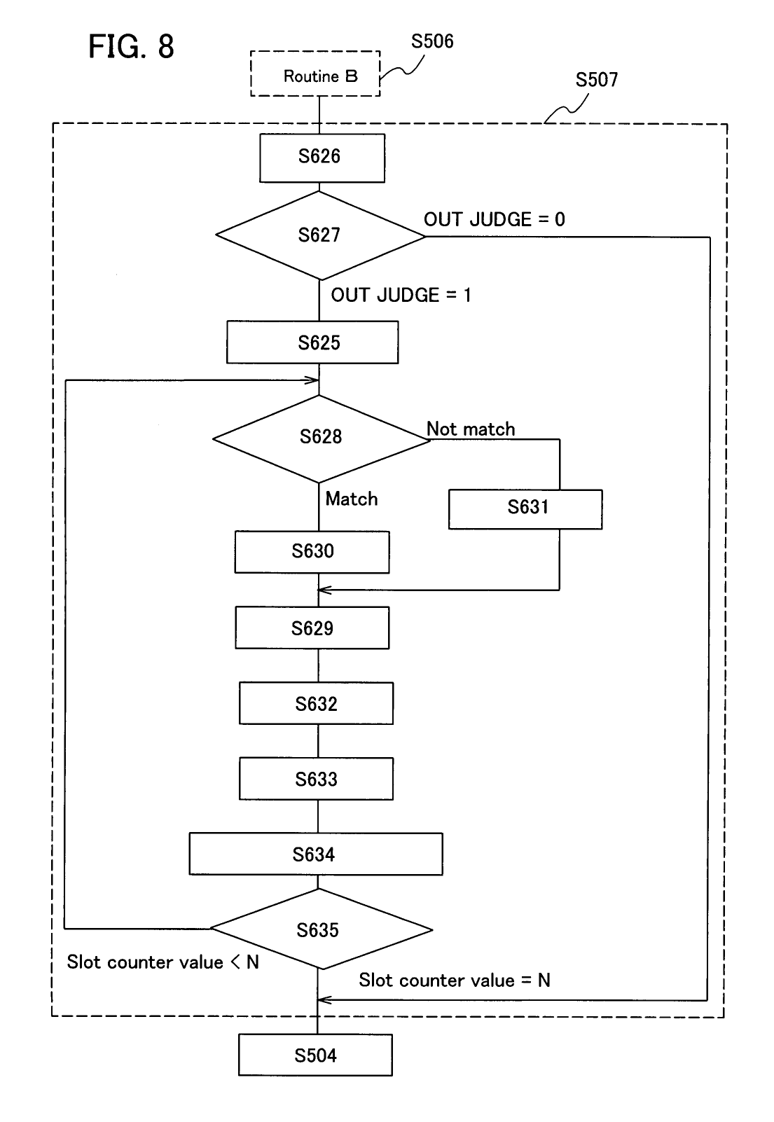

Next, FIG. 8 shows a flowchart of the N-slot power consumption reduction routine 201D (in this embodiment mode, N=16) (routine C in FIG. 5). When the CPU 102 starts a process of the N-slot, the CPU 102 waits until it detects that the state of the control register 117 is EOF. The CPU 102 detects EOF (S626). Subsequently, the CPU 102 determines the OUTJUDGE (S627). If the OUTJUDGE flag is 1, the CPU 102 substitutes a slot counter value 0 for the N-slot counter routine 201E (S625).

Meanwhile, in S626, if the OUTJUDGE flag is 0, the main program is terminated (S504). Next, the CPU 102 compares the slot register value stored in the RAM with the slot counter value, using the N-slot counter routine 201E. If the values correspond, the CPU 102 writes the UID value of each semiconductor device to the control register 117 (S630). Meanwhile, if they do not correspond, the CPU 102 writes 0 to the control register 117 (S631). Next, the CPU 102 starts transmission of data to the reader/writer (S629), and the controller 105 stops the CPU 102 (S632). When transmission of the data has finished, the controller 105 makes the CPU 102 operate again (S633). Next, the CPU 102 increases the slot counter value by 1 (S634). The CPU 102 determines the slot counter value (S635). When the slot counter value is N (here, N is 16), the main program is terminated (S504). In S635, when the slot counter value is less than N (here, N is 16), the CPU 102 once again compares the slot register value stored in the slot register with the slot counter value, using the N-slot counter routine 201E. Note that here, the slot counter value refers to the number of times the slot counter routine is executed.

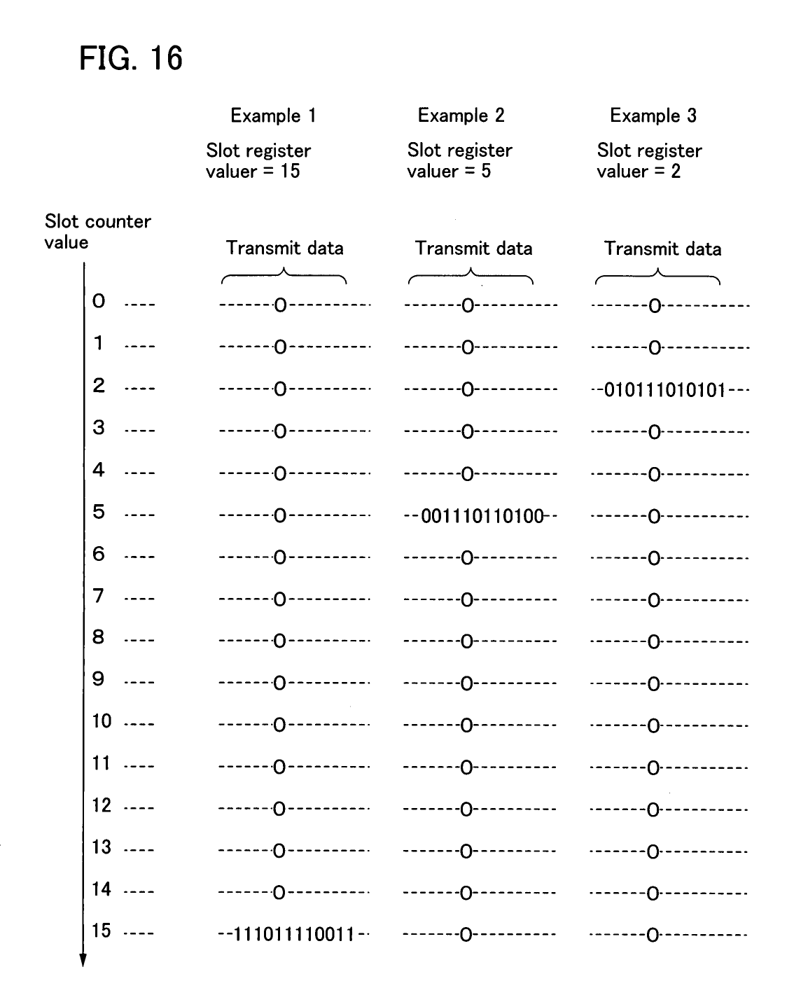

FIG. 16 specifically shows a process of the N-slot power consumption reduction routine of FIG. 8. Values used as examples here are shown in Table 3. Note that the UID values are shown in binary notation and the slot register values are shown in decimal notation. Further, slot counter values in the description are shown in decimal notation.

TABLE 3

| | UID value | Slot register value |
|---|---|---|
| Example 1 | 111011110011 | 15 |
| Example 2 | 001110110100 | 5 |
| Example 3 | 010111010101 | 2 |

When a slot register value 15 from Example 1 in Table 3 is used in the N-slot power consumption reduction routine, the CPU 102 compares the slot register value with the slot counter value using the slot counter routine, in S628. Only when the values correspond to each other, the CPU 102 writes the UID value 111011110011 to the control register 117. Therefore, in S629, the UID value 111011110011 is transmitted to the reader/writer only when the slot counter value is 15. When the slot counter value is a value other than 15, 0 is transmitted to the reader/writer.

When a slot register value 5 from Example 2 in Table 3 is used in the N-slot power consumption reduction routine, the CPU 102 compares the slot register value with the slot counter value using the slot counter routine, in S628. Only when the values correspond to each other, the CPU 102 writes the UID value 001110110100 to the control register 117. Therefore, in S629, the UID value 001110110100 is transmitted to the reader/writer only when the slot counter value is 5. When the slot counter value is a value other than 5, 0 is transmitted to the reader/writer.

When a slot register value 2 from Example 3 in Table 3 is used in the N-slot power consumption reduction routine, the CPU 102 compares the slot register value with the slot counter value using the slot counter routine, in S628. Only when the values correspond to each other, the CPU 102 writes the UID value 010111010101 to the control register 117. Therefore, in S629, the UID value 010111010101 is transmitted to the reader/writer only when the slot counter value is 2. When the slot counter value is a value other than 2, 0 is transmitted to the reader/writer.

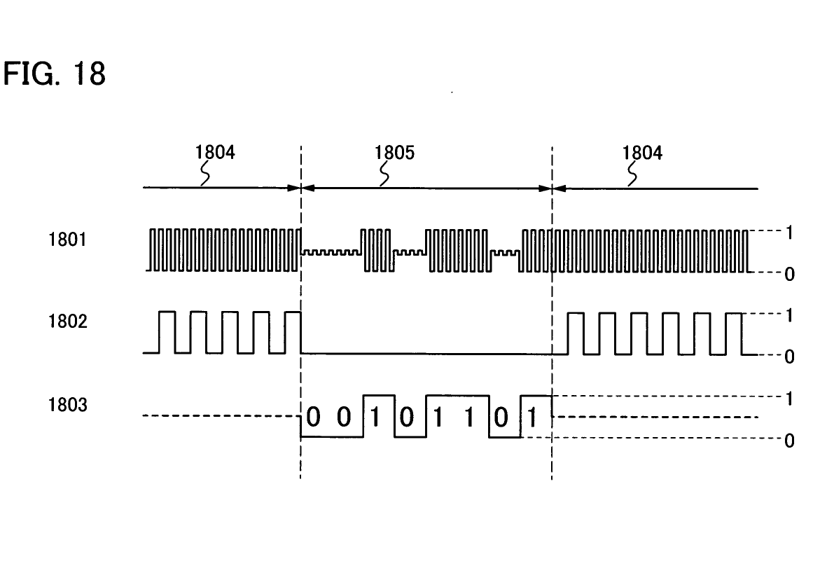

Next, a signal related to transmission will be described, with reference to the timing chart shown in FIG. 18. A first signal 1801 corresponds to the transmit signal 121 in FIG. 1. A second signal 1802 corresponds to the CPU clock signal 132 in FIG. 1. A third signal 1803 corresponds to transmit data 123 in FIG. 1. Further, in FIG. 18, a computation period 1804 is the same as the computation period 1710 in FIG. 17.

After the computation period 1804, when transmission of data to the reader/writer is started, the encoder circuit 119 encodes data in the control register 117, and outputs it to the modulation circuit 113 as the third signal 1803. Further, the clock generator circuit 111 stops supplying clocks to the CPU. Specifically, the second signal 1802 is set to “1” or “0” (in this embodiment mode, it is set to 0). That is, “CPU stop” which is S632 in FIG. 8 refers to stopping the supply of clocks to the CPU.

Next, the modulation circuit 113 modulates the third signal 1803 and transmits it to the reader/writer as the first signal 1801. The first signal 1801 is an electromagnetic wave that oscillates at a frequency of a carrier wave. Modulation refers to conversion to an analog value with “1” as the amplitude maximum and “0” as the amplitude minimum. When modulation has finished, the clock generator circuit 111 starts supplying clocks to the CPU again. That is, “CPU operation”, which is S633 in FIG. 8, refers to starting the supply of clocks to the CPU. Note that the period of time from the start to the finish of modulation is a transmission period 1805. After the transmission period 1805 has finished, the computation period 1804 starts again.

By employing the above-described mode, in a semiconductor device having a function of reducing power consumption when an anti-collision operation is performed, by using a controller, a central processing unit is stopped when a signal is transmitted to the outside, so power consumption is reduced. Therefore, when an arithmetic circuit operates simultaneously with a storage device and a modulation circuit, that is, when the modulation circuit modulates a carrier and thereby a communication signal is transmitted from an antenna, power can be stabilized and operation during the transmission can be performed reliably. Further, in a semiconductor device having a function of repeatedly performing a transmit operation a plurality of times, it is not necessary to remake the semiconductor device from the stage of mask design due to a change in the specifications accompanying a change in a method of operation. Therefore, manufacturing cost and manufacturing time can be reduced. Further, there are no concerns such as whether a semiconductor device which is remade due to a change in mask design will malfunction.

Note that this embodiment mode may be freely combined with any part of the embodiments in this specification.

### Embodiment 1

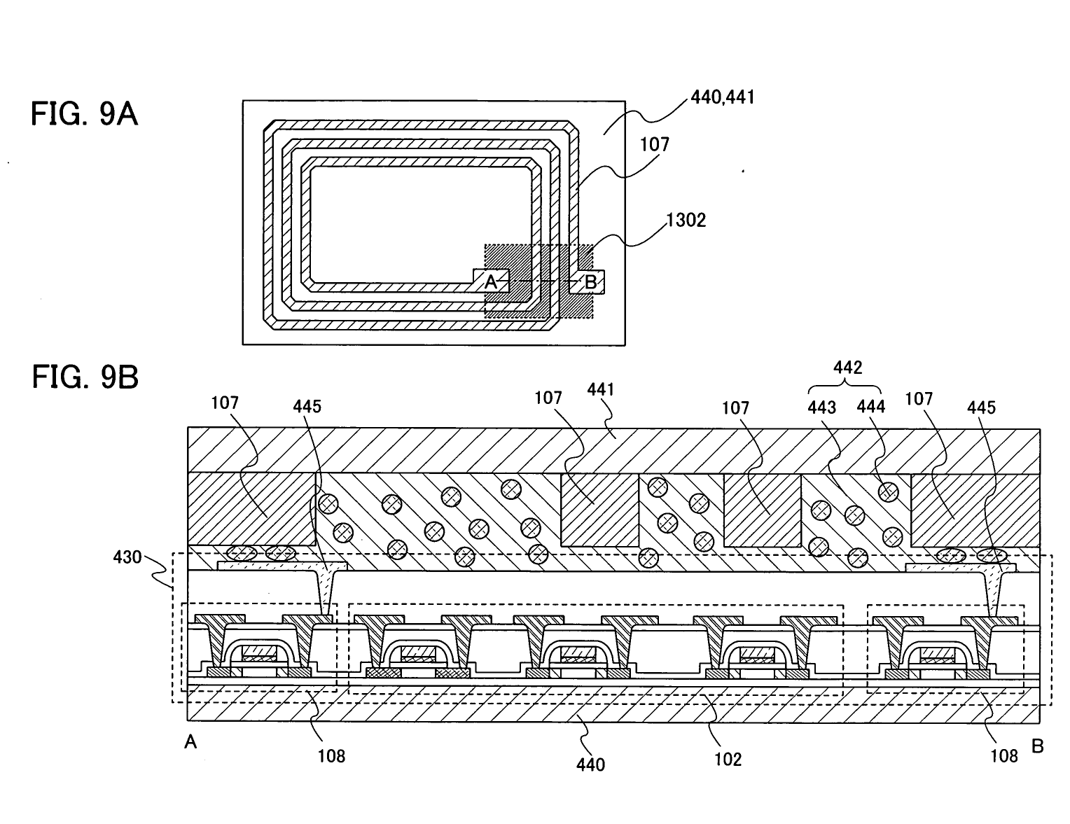

Next, an example of a structure of the above-described semiconductor device will be described, with reference to the drawings. FIG. 9A shows a top view of a semiconductor device of this embodiment, and FIG. 9B shows a cross section taken along the line A-B in FIG. 9A.

As shown in FIG. 9A, in the semiconductor device of this embodiment, an integrated circuit 1302 and an antenna 107 are sandwiched between substrates 440 and 441. The integrated circuit 1302 includes the analog portion 115, excluding the antenna 107, and the digital portion 106 which are included in FIG. 1.

As shown in FIG. 9B, in the semiconductor device 101, the antenna 107 provided over the substrate 441 and an element formation layer 430 provided over the substrate 440 are firmly attached to each other by an anisotropic conductive adhesive 442. Further, the anisotropic conductive adhesive 442 includes an organic resin 443 and conductive particles 444. A connecting terminal 445 of the element formation layer 430 is electrically connected to the antenna 107 by the conductive particles 444.

Note that there is no particular limitation on the connection between the connecting terminal 445 and the antenna 107. For example, the antenna 107 and the connecting terminal 445 may be connected using a wire bonding connection or a bump connection. Further, an ACF (anisotropic conductive film) can be used to attach the connecting terminal 445 and the antenna 107 to each other.

The element formation layer 430 includes parts of the analog portion 115, excluding the antenna 107, and the digital portion 106 of the semiconductor device shown in FIG. 1. Further, here, as the element formation layer 430, a thin film transistor which is included in the resonant circuit 108 is shown as a representative example of part of the analog portion 115, and a thin film transistor which is included in the CPU 102 is shown as a representative example of part of the digital portion 106.

Note that here, thin film transistors are used in the resonant circuit 108 and the digital portion 106; however, each circuit also includes a resistive element, a capacitative element, a rectifying element, and the like.

Further, as the element formation layer 430, a MOS transistor formed on a Si wafer may be used.

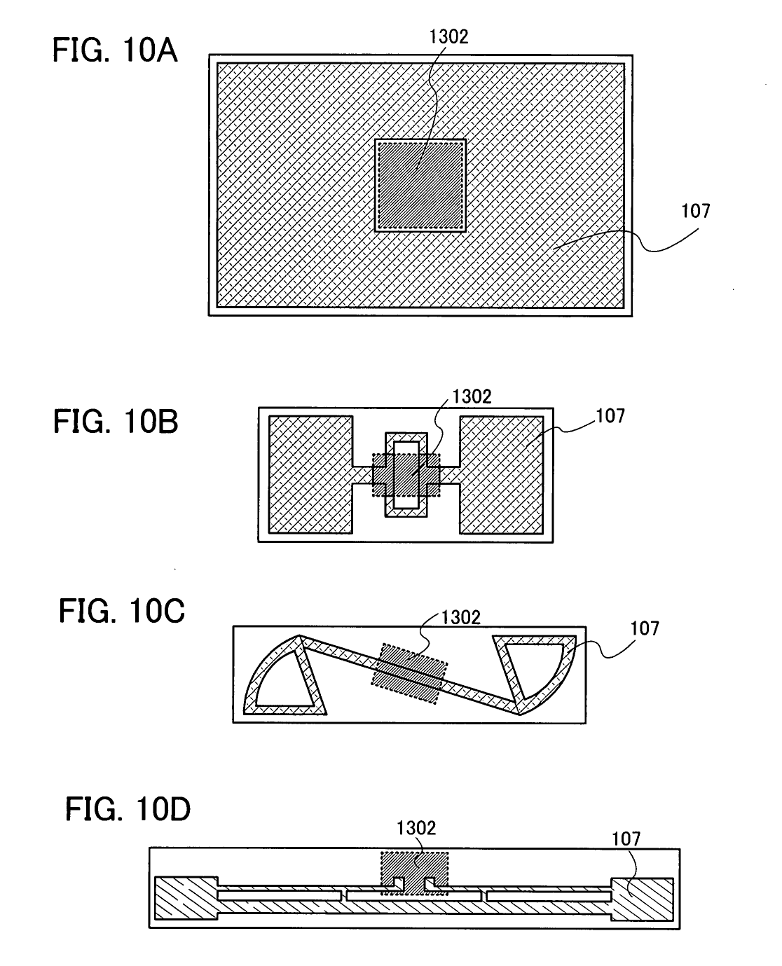

Forms of an antenna which can be used in a semiconductor device of the invention are described below. As an antenna form which can be used in the semiconductor device, a coiled antenna such as the one shown in FIG. 9A can be used. Further, a structure may be used in which the antenna 107 is disposed all around the integrated circuit 1302 which is over the substrate, as shown in FIG. 10A. Further, as shown in FIG. 10B, the integrated circuit 1302 which is over the substrate may be provided with the antenna 107 for receiving high frequency electromagnetic waves. Alternatively, as shown in FIG. 10C, the integrated circuit 1302 which is over the substrate may be provided with the antenna 107 which is 180 degree non-directional (so that it can receive signals equally from any direction). Further alternatively, as shown in FIG. 10D, the integrated circuit 1302 which is over the substrate may provided with the antenna 107 having a long rod-shape. Further, a patch antenna or a ceramic antenna may also be used. Further, the shape of the conductive layer which functions as an antenna is not limited to a linear shape. Taking a wavelength of an electromagnetic wave into consideration, the shape of the conductive layer may be curved, meandering, or a combination of these.

Here, an example is shown in FIG. 9B in which the element formation layer 430 and the antenna 107 are provided on separate substrates to each other and are electrically connected by an anisotropic conductive material. However, the invention is not limited to this. The antenna 107 may be provided in the element formation layer 430.

Further, the appropriate length for the antenna differs according to the frequency used for reception. Therefore, generally, the length preferably corresponds to a wavelength divided by an integer. For example, in a case where the frequency is 2.45 GHz, the length of the antenna may be about 60 mm (½ a wavelength) or about 30 mm (¼ of a wavelength).

A frequency of a signal transmitted or received between the antenna 107 and the reader/writer may be 125 kHz, 13.56 MHz, 915 MHz, 2.45 GHz, or the like. Each of these frequencies is set by ISO standards or the like. Of course, the frequency of the signal transmitted or received between the antenna 107 and the reader/writer is not limited to this, and for example, any of the following frequencies can also be used: 300 GHz to 3 THz, which is a submillimeter wave, 30 GHz to 300 GHz, which is a millimeter wave, 3 GHz to 30 GHz, which is a microwave, 300 MHz to 3 GHz, which is an ultrahigh frequency wave, 30 MHz to 300 MHz, which is a very high frequency wave, 3 MHz to 30 MHz, which is a high frequency wave, 300 kHz to 3 MHz, which is a medium frequency wave, 30 kHz to 300 kHz, which is a low frequency wave, or 3 kHz to 30 kHz, which is a very low frequency wave. Further, a signal transmitted or received between the antenna 107 and the reader/writer is a modulated carrier wave. As a method of modulating the carrier wave, analog modulation or digital modulation may be used. Amplitude modulation, phase modulation, frequency modulation, or spread spectrum may also be used. Preferably, amplitude modulation or frequency modulation is used.

As a method of transmitting a signal for the above-described semiconductor device which is capable of inputting and outputting data contactlessly, an electromagnetic coupling method, an electromagnetic induction method, a microwave method, or the like can be used. Preferably, the transmission method is selected as appropriate taking an intended use of the device into account, and an antenna which is suitable for the transmission method is provided.

### Embodiment 2

In this embodiment mode, a structure including a booster antenna circuit (hereinafter referred to as a booster antenna) for a semiconductor device described in the embodiment mode and embodiment above will be described with reference to the drawings.

Note that the booster antenna described in this embodiment refers to an antenna (which is hereinafter referred to as a booster antenna) having a size larger than that of an antenna (which is hereinafter referred to as a chip antenna or an antenna circuit) included in the semiconductor device which receives a signal from the reader/writer and outputs the signal to an integrated circuit. The booster antenna refers to an antenna that can efficiently transmit a signal that is sent from a reader/writer or a charger to the destination of the signal, the semiconductor device, by resonating the signal at a frequency band which is used and magnetically coupling the chip antenna with the booster antenna itself through a magnetic field. Since the booster antenna is magnetically coupled with the chip antenna through the magnetic field, there is no need to directly connect the booster antenna to the chip antenna and the integrated circuit, which is advantageous. Further, a capacitative element may be provided in the booster antenna to control capacitance.

There is no particular limitation on the form of the antennas of the chip antenna 107 and the booster antenna. For example, an antenna with the form shown in FIG. 10A, described in Embodiment 1, can be employed. However, taking the function of the booster antenna into consideration, an antenna with a form larger than that of the antenna circuit which is magnetically coupled with the booster antenna is preferably employed as the booster antenna.

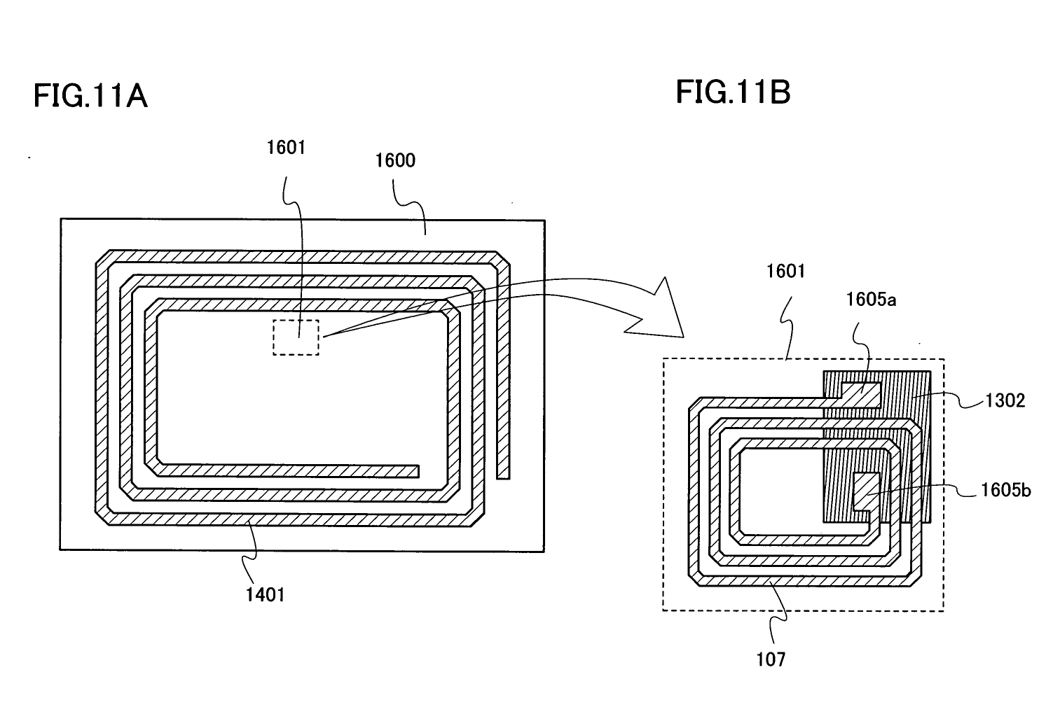

Further, in this embodiment, signals received by the antenna 107 and a booster antenna 1401 are preferably communicated by an electromagnetic induction method. Therefore, a structure including a coiled antenna 107 and a coiled booster antenna 1401 is preferable. FIGS. 11A and 11B show a structure in which the coiled antenna 107, the coiled booster antenna 1401, and the integrated circuit 1302 are provided over one surface of a substrate 1600.

As shown in FIG. 11A, the semiconductor device includes a region 1601 where the integrated circuit 1302 and the chip antenna 107 are formed and the booster antenna 1401, which are over the substrate 1600. Note that concerning the region 1601 where the integrated circuit 1302 and the chip antenna 107 are formed, as shown in FIG. 11B, the integrated circuit 1302 and the chip antenna 107 are formed, and a connecting terminal 1605a and a connecting terminal 1605b of the chip antenna 107 are each connected to the integrated circuit 1302.

The forms of the booster antenna 1401 and the chip antenna 107 are not limited to those shown in the drawings. Various forms can be used, as long as the transmitting and receiving frequencies tune in with each other. Preferably, the booster antenna 1401 takes the form of a loop antenna, while the chip antenna 107 takes the form of a miniature loop antenna. Note that the arrangement and structure of the semiconductor device are not limited to this, and the area ratio between the chip antenna 107 and the booster antenna 1401 can be selected as appropriate. In FIGS. 11A and 11B, the integrated circuit 1302 and the booster antenna 1401 are disposed over the substrate 1600. However, the booster antenna 1401 may be provided over the back surface of the substrate 1600, for example.

The semiconductor device of this embodiment has the booster antenna in addition to the structure described in Embodiment 1. Therefore, the semiconductor device of this embodiment has the advantage of being able to transmit and receive data between an RFID and a reader/writer more reliably.

### Embodiment 3

In this embodiment, uses of a semiconductor device of the invention that exchanges data by radio communication will be described. A semiconductor device of the invention can be used as a so-called ID label, ID tag, or ID card, which is provided in, for example, bills, coins, securities, bearer bonds, documents (such as driver's licenses or resident's cards), packaging containers (such as wrapping paper or bottles), storage media (such as DVD software or video tapes), vehicles (such as bicycles), personal belongings (such as bags or glasses), foods, plants, animals, clothing, everyday articles, tags on goods such as an electronic appliance or on packs. An electronic appliance refers to a liquid crystal display device, an EL display device, a television set (also called simply a TV set, a TV receiver, or a television receiver), a mobile phone, or the like.

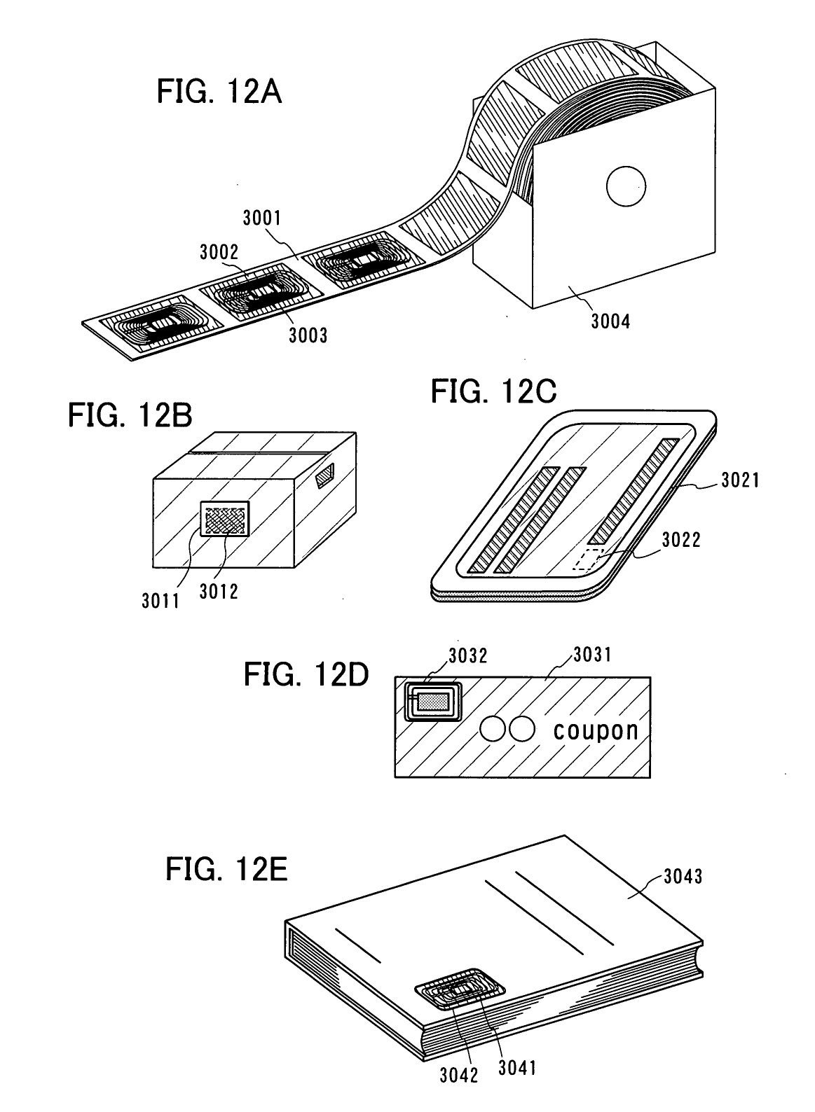

In this embodiment, applications of the invention and an example of a product which includes an application of the invention are described with reference to FIGS. 12A to 12E.

FIG. 12A shows examples of completed products including semiconductor devices of the invention. A plurality of ID labels 3003 each including a semiconductor device 3002 are formed on a label board (separate paper) 3001. The ID labels 3003 are stored in a box 3004. In addition, on the ID label 3003, information about a product or service (a name of the product, a brand, a trademark, a trademark owner, a seller, a manufacturer, or the like) is written, while an ID number that is unique to the product (or the type of the product) is assigned to the included semiconductor device to make it possible to easily detect forgery, infringement of intellectual property rights such as patent rights and trademark rights, and illegality such as unfair competition. In addition, a large amount of information that cannot be clearly written on a container of the product or the label (for example, the production area, selling area, quality, raw material, efficacy, use, quantity, shape, price, production method, usage, time of the production, time of use, expiration date, instructions for the product, information about the intellectual property of the product, or the like) can be input to the semiconductor device so that a client or a consumer can access the information by using a simple reader. Further, the semiconductor device is structured such that the producer of a product can easily rewrite or erase information, for example, but a client or a consumer cannot.

FIG. 12B shows a label-shaped ID tag 3011 including a semiconductor device 3012. By providing a product with the ID tag 3011, management of the product can be simplified. For example, in a case where a product is stolen, the product can be traced, so the culprit can be identified quickly. Thus, by providing the ID tag, products that are superior in so-called traceability can be distributed.

FIG. 12C shows an example of a completed ID card 3021 including a semiconductor device 3022 of the invention. The ID card 3021 may be any kind of card, including a cash card, a credit card, a prepaid card, an electronic ticket, electronic money, a telephone card, a membership card, or the like.

FIG. 12D shows an example of a completed bearer bond 3031. A semiconductor device 3032 is embedded in the bearer bond 3031 and is protected by a resin which forms the periphery of the semiconductor device. Here, the resin is filled with a filler. The bearer bond 3031 can be formed in the same manner as an ID label, an ID tag, or an ID card of the invention. Note that the aforementioned bearer bond may be a stamp, a ticket, an admission ticket, a merchandise coupon, a book coupon, a stationery coupon, a beer coupon, a rice coupon, various types of gift coupon, various types of service coupon, or the like. Needless to say, the bearer bond is not limited thereto. In addition, when the semiconductor device 3032 of the invention is provided in bills, coins, securities, bearer bonds, documents, or the like, an authentication function can be provided. Therefore, by using the authentication function, forgery can be prevented.

FIG. 12E shows a book 3043 to which an ID label 3041 including a semiconductor device 3042 of the invention is attached. The semiconductor device 3042 of the invention is firmly attached in or on goods by being attached to a surface or embedded therein, for example. As shown in FIG. 12E, the semiconductor device 3042 can be embedded in the paper of a book, or embedded in an organic resin of a package. Since the semiconductor device 3042 of the invention can be small, thin, and lightweight, it can be firmly attached to or in goods without spoiling their design.

In addition, the efficiency of a system such as an inspection system can be improved by provision of the semiconductor device of the invention in, for example, packaging containers, storage media, personal belongings, foods, clothing, everyday articles, electronic appliances, or the like, although this is not illustrated here. Further, by providing the semiconductor device on or in a vehicle, counterfeit and theft can be prevented. Living things such as animals can be easily identified by implanting the individual living things with the semiconductor device. For example, year of birth, sex, breed, or the like can be easily discerned by implanting the semiconductor device in living things such as domestic animals.

Thus, a semiconductor device of the invention can be applied to any goods (including living things).

This embodiment can be freely combined with the preceding embodiment mode and embodiments.

This application is based on Japanese Patent Application serial no. 2006-160516 filed in Japan Patent Office on 9 Jun., 2006, the entire contents of which are hereby incorporated by reference.

What is claimed is:

1. A semiconductor device comprising:
a central processing unit;
a controller;
a storage device; and
a circuit for transmitting and receiving signals to and from an outside,
wherein a program for using the controller to reduce power consumption of the central processing unit when a signal is transmitted to the outside is stored in the storage device.

2. The semiconductor device according to claim 1, wherein the controller stops the central processing unit when a signal is transmitted to the outside.

3. The semiconductor device according to claim 1, wherein the central processing unit executes the program to stop the central processing unit when a signal is transmitted to the outside.

4. The semiconductor device according to claim 1, wherein the program includes a plurality of routines.

5. The semiconductor device according to claim 4, wherein the plurality of routines includes a command determination routine, a unique identifier value processing routine, a mask value comparison routine, an N-slot counter routine, and an N-slot power consumption reduction routine.

6. The semiconductor device according to claim 4, wherein the plurality of routines reduces power consumption at a time of an anti-collision operation.

7. The semiconductor device according to claim 1, wherein the storage device includes a read-only memory and a random-access memory.

8. The semiconductor device according to claim 1, wherein the controller includes at least one selected from the group consisting of a CPU interface, a control register, a code extraction circuit, and an encoder circuit.

9. The semiconductor device according to claim 1, wherein the circuit for transmitting and receiving signals to and from the outside includes at least one selected from the group consisting of an antenna, a resonant circuit, a power supply circuit, a reset circuit, a clock generator circuit, a demodulation circuit, a modulation circuit, and a power supply generating circuit.

10. A semiconductor device comprising:
a central processing unit;
a controller;
a storage device; and
a circuit for transmitting and receiving signals to and from an outside,
wherein a program for using the controller to reduce power consumption of the central processing unit when a signal is transmitted to the outside is stored in the storage device, and
wherein execution of the program causes the controller to stop the central processing unit.

11. The semiconductor device according to claim 10, wherein the controller stops the central processing unit when a signal is transmitted to the outside.

12. The semiconductor device according to claim 10, wherein the central processing unit executes the program to stop the central processing unit when a signal is transmitted to the outside.

13. The semiconductor device according to claim 10, wherein the program includes a plurality of routines.

14. The semiconductor device according to claim 13, wherein the plurality of routines includes a command determination routine, a unique identifier value processing routine, a mask value comparison routine, an N-slot counter routine, and an N-slot power consumption reduction routine.

15. The semiconductor device according to claim 13, wherein the plurality of routines reduces power consumption at a time of an anti-collision operation.

16. The semiconductor device according to claim 10, wherein the storage device includes a read-only memory and a random-access memory.

17. The semiconductor device according to claim 10, wherein the controller includes at least one selected from the group consisting of a CPU interface, a control register, a code extraction circuit, and an encoder circuit.

18. The semiconductor device according to claim 10, wherein the circuit for transmitting and receiving signals to and from the outside includes at least one selected from the group consisting of an antenna, a resonant circuit, a power supply circuit, a reset circuit, a clock generator circuit, a demodulation circuit, a modulation circuit, and a power supply generating circuit.

19. A semiconductor device comprising:
a central processing unit;
a controller;
a storage device; and
a circuit for transmitting and receiving signals to and from an outside,
wherein a program for using the controller to reduce power consumption of the central processing unit when a signal is transmitted to the outside is stored in the storage device, and
wherein the central processing unit executes the program to stop the central processing unit.

20. The semiconductor device according to claim 19, wherein the controller stops the central processing unit when a signal is transmitted to the outside.

21. The semiconductor device according to claim 19, wherein the central processing unit executes the program to stop the central processing unit when a signal is transmitted to the outside.

22. The semiconductor device according to claim 19, wherein the program includes a plurality of routines.

23. The semiconductor device according to claim 22, wherein the plurality of routines includes a command determination routine, a unique identifier value processing routine, a mask value comparison routine, an N-slot counter routine, and an N-slot power consumption reduction routine.

24. The semiconductor device according to claim 22, wherein the plurality of routines reduces power consumption at a time of an anti-collision operation.

25. The semiconductor device according to claims 19, wherein the storage device includes a read-only memory and a random-access memory.

26. The semiconductor device according to claims 19, wherein the controller includes at least one selected from the group consisting of a CPU interface, a control register, a code extraction circuit, and an encoder circuit.

27. The semiconductor device according to claim 19, wherein the circuit for transmitting and receiving signals to and from the outside includes at least one selected from the group consisting of an antenna, a resonant circuit, a power supply circuit, a reset circuit, a clock generator circuit, a demodulation circuit, a modulation circuit, and a power supply generating circuit.
